(19) United States
(12) Patent Application Publication
(10) Pub. No.: US 2002/0043675 A1
(43) Pub. Date: Apr. 18, 2002

(54) Memory device incorporating therein a HfO2 layer as a barrier layer

(76) Inventors: Chang-Koo Lee, Ichon-shi (KR); Chan Lim, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/904,475

(22) Filed: Jul. 16, 2001

(30) Foreign Application Priority Data
Jul. 31, 2000 (KR) 2000-44386

(51) Int. Cl. H01L 29/76; H01L 29/94; H01L 31/062; H01L 31/113; H01L 31/119; H01L 27/108

(52) U.S. Cl. 257/295; 257/296

(57) ABSTRACT

A memory device including a semiconductor substrate provided with a transistor; a ferroelectric capacitor provided with a bottom electrode placed on the semiconductor substrate, a ferroelectric layer formed on the bottom electrode and a top electrode formed on the ferroelectric layer; and a HfO₂ layer for covering the ferroelectric capacitor.

### FIELD OF THE INVENTION

The present invention relates to a ferroelectric memory device and, more particularly, to a ferroelectric memory device which is capable of protecting a ferroelectric capacitor from being degraded by a plasma etching process and the formation of an interlayer dielectric (ILD) layer.

### DESCRIPTION OF THE PRIOR ART

A ferroelectric random access memory (FeRAM) is a nonvolatile semiconductor memory device with the information storing function of a dynamic random access memory (DRAM), the speedy information treatment of a static random access memory (SRAM), and the information storing function of a flash memory. It has a low operational voltage and speedy information processing compared with the conventional flash memory and an electrically erasable programmable read only memory (EEPROM).

Generally, in the DRAM, a capacitor which utilizes SiO₂ or SiON as a dielectric material returns to its original status when an electric field applied thereto is removed. However, in the case of FeRAM, when an electric field of positive value is applied thereto, the FeRAM enters a polarization state (+Pr) which corresponds to a data “1”. Whereas, when the electric field is removed, the FeRAM enters a polarization state (−Pr) which corresponds to a data “0”. As described, a ferroelectric capacitor could store a data for its material characteristic even when the voltage is turned off.

SrBi₂Ta₂O₉ (SBT) or Pb(Zrₓ, Ti₁₋ₓ) O₃ (PZT) is mainly used as a storage material of FeRAM. A ferroelectric material has a dielectric constant being on the order of 10²-10³ in normal temperature and has two stabilized remnant polarization states. Therefore, the ferroelectric material is suitable for application to the nonvolatile memory device as a capacitor dielectric.

The manufacturing processes of the FeRAM device are easily developed since they are compatible with that of the DRAM. In fact, the ferroelectric device memory could be manufactured by adding the ferroelectric capacitor as an information storing device in the conventional DRAM.

FIG. 1 is a cross-sectional view illustrating a conventional FeRAM device. A first interlayer dielectric (ILD) layer 14 is formed on a semiconductor substrate 10 provided with a transistor, an isolation region 11, a gate dielectric layer (not shown), a gate electrode 12 and source/drain regions 13. A capacitor is formed on the first ILD layer 14, with the capacitor consisting of a bottom electrode 15, a ferroelectric layer 16 and a top electrode 17. A second ILD layer 18 is formed on the capacitor. After that, the top electrode 17 is exposed, thereby obtaining a first contact hole. The source/drain region 13 is also exposed, thereby obtaining a second contact hole. Finally, a first metal line 19A is formed to connect the capacitor to the transistor. A bit line 19B and an intermetal dielectric layer 20 are formed on the whole structure, successively.

The ferroelectric capacitor characteristics can be changed by the following processes. Especially, a plasma in an etching process, penetration of hydrogen in a dielectric layer and, the formation of a planarized oxidation layer can degrade the ferroelectric capacitor. To minimize the damage, a plasma source development, a source voltage and a regulated bias voltage condition are needed. And to prevent deterioration due to succeeding oxidation layer deposition, a process without using a silane gas has to be adopted. However, the types of films which meet the above requirements are limited so that it is difficult to utilize the above process.

### SUMMARY OF THE INVENTION

It is, therefore, an object of the present invention to provide a ferroelectric memory device which is capable of protecting a ferroelectric capacitor from being degraded by a plasma etching process and the formation of an interlayer dielectric.

In accordance with one aspect of the present invention, there is provided a memory device, comprising a semiconductor substrate; a ferroelectric capacitor provided with a bottom electrode placed on the semiconductor substrate, a ferroelectric layer formed on the bottom electrode and a top electrode formed on the ferroelectric layer; and a HfO₂layer for covering the ferroelectric capacitor.

In accordance with another aspect of the present invention, there is provided a memory device, comprising a semiconductor substrate provided with a transistor formed thereon; an interlayer dielectric (ILD) layer formed on the transistor and the semiconductor substrate; a ferroelectric capacitor provided with a bottom electrode placed on the semiconductor substrate, a ferroelectric layer formed on the bottom electrode and a top electrode formed on the ferroelectric layer; an interconnection metal layer for electrically connecting the ferroelectric capcitor to the transistor through the ILD layer; and a HfO₂ layer formed on the interconnection metal layer.

In accordance with yet another aspect of the present invention, there is provided a memory device, comprising a semiconductor substrate provided with a transistor; a first ILD layer formed on the transistor; a ferroelectric capacitor provided with a bottom electrode formed on the first ILD layer, a ferroelectric layer formed on the bottom electrode and a top electrode formed on the ferroelectric layer; a HfO₂ layer formed on the ferroelectric capacitor; a second ILD layer formed on the HfO₂ layer and the first ILD layer; a first contact hole to expose a portion of the transistor; a second contact hole to expose a portion of the ferroelectric capacitor; and an interconnection metal layer, formed on the second ILD layer, for electrically connecting the capacitor to the transistor.

### BRIEF DESCRIPTION OF THE DRAWINGS

The above and other objects and features of the present invention will become apparent from the following description of the preferred embodiments given in conjunction with the accompanying drawings, in which;

FIG. 1 is a cross-sectional view illustrating a conventional FeRAM device;

FIG. 2 is a cross-sectional view showing a FeRAM device in accordance with a first preferred embodiment of the present invention;

FIG. 3 is a cross-sectional view showing a FeRAM device in accordance with a second preferred embodiment of the present invention;

FIG. 4 is a cross-sectional view showing a FeRAM device in accordance with a third preferred embodiment of the present invention; and

FIGS. 5A and 5B are graphs showing ferroelectric characteristics of polarization versus applied voltage for a conventional FeRAM device and for the present FeRAM device, respectively.

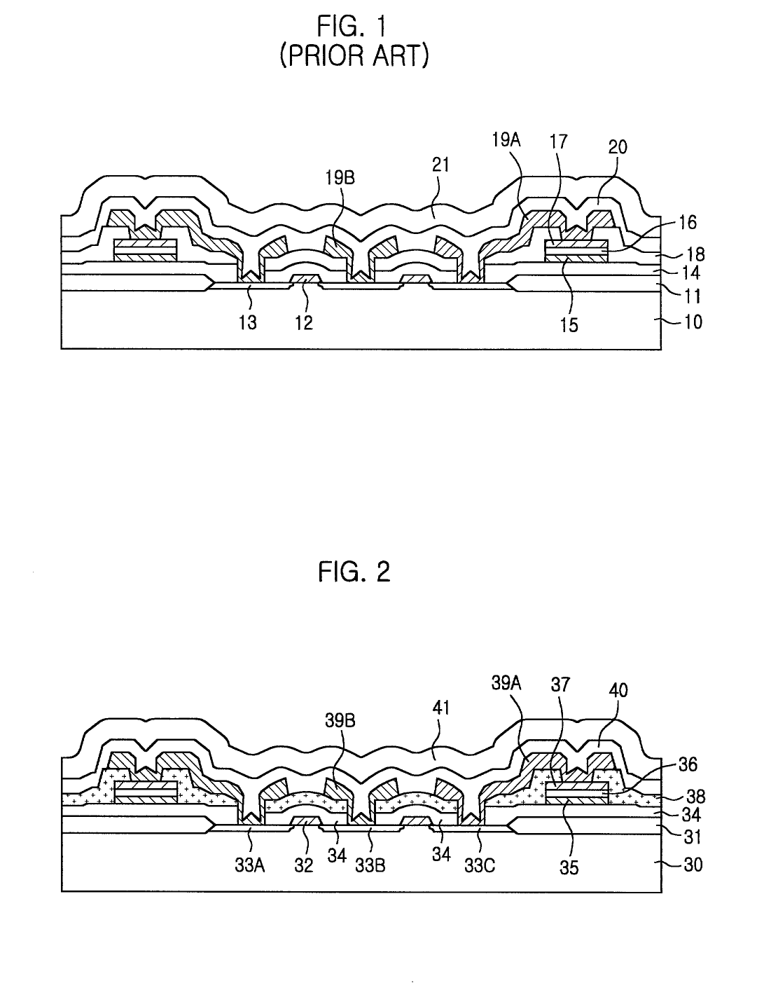

### DETAILED DESCRIPTION OF THE PREFERRED EMBODIMENTS

FIG. 2 is a cross-sectional view showing a FeRAM device in accordance with a first preferred embodiment of the present invention.

An isolation region 31 is formed on a semiconductor substrate 30, wherein the semiconductor substrate 30 is provided with a transistor including a gate dielectric layer (not shown) formed on the semiconductor substrate 30 and a gate electrode 32 formed thereon, and source/drain regions 33A, 33B, 33C. An interlayer dielectric (ILD) layer 34 covers the semiconductor substrate 30 including the transistor and the isolation region 31. A ferroelectric capacitor is formed on a portion of the ILD layer 34 which is placed over the isolation region 31. The ferroelectric capacitor includes a bottom electrode 35, a ferroelectric layer 36 and a top electrode 37. The ferroelectric layer 36 is disposed between the bottom electrode 35 and the top electrode 37. A HfO₂ layer 38 covers the ferroelectric capacitor. After that, a first contact hole is formed on the top electrode 37 of the ferroelectric capacitor by removing a portion of the HfO₂ layer 38, thereby exposing a portion of top electrode 37. A second contact hole is formed on the source/drain regions 33A, 33B, 33C by opening portions of the HfO₂ layer 38 and the ILD layer 34.

A first interconnection metal layer 39A connects the ferroelectric capacitor and the transistor through the first contact hole and the second contact hole. An intermetal dielectric layer 40 and a second interconnection metal layer 41 cover the whole structure including the interconnection metal layer 39A and bit line 39B, successively. The bit line 39B is electrically connected to the source/drain region 33B to apply an electric potential. Although the bit line 39B actually extends in right and left directions by passing the intermetal dielectric layer 40, the drawing does not show these parts of the bit line 39B.

It should be noted that the HfO₂ layer 38 can be formed on the interconnection metal layer 41 to cover the whole structure including the ferroelectric capacitor.

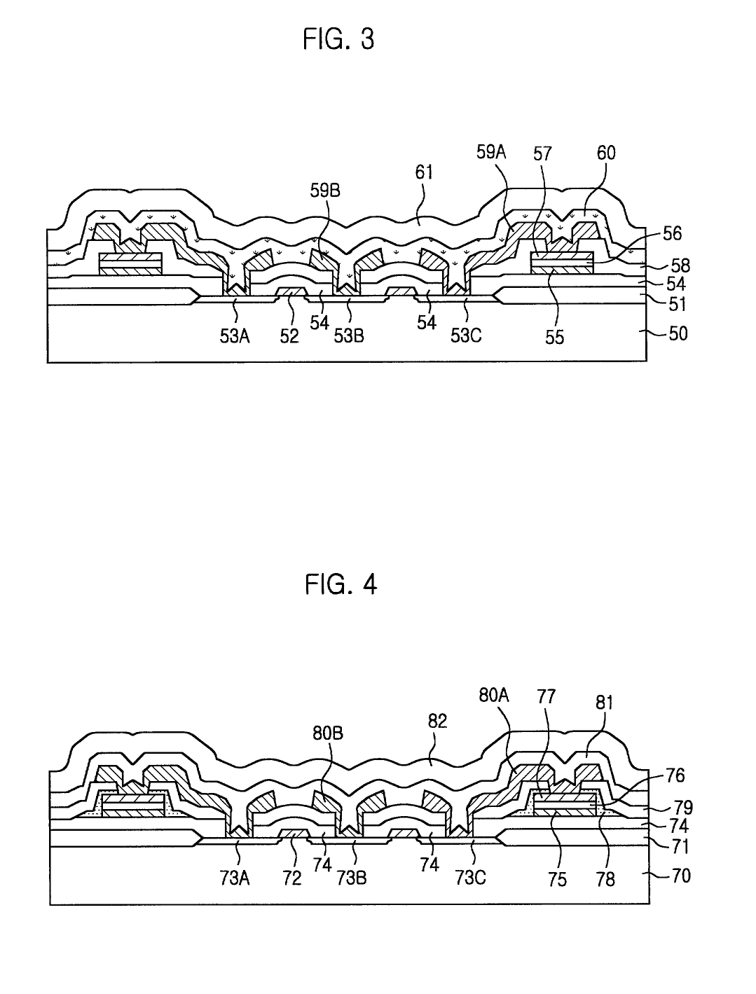

FIG. 3 is a cross-sectional view showing a FeRAM device in accordance with the second preferred embodiment of the present invention. An isolation region 51 is formed on a semiconductor substrate 50, wherein the semiconductor substrate 50 is provided with a transistor including a gate dielectric layer (not shown) formed on the semiconductor substrate 50, a gate electrode 52, and source/drain regions 53A, 53B, 53C. A first ILD layer 54 covers the semiconductor substrate 50 including the transistor and the isolation region 51. A ferroelectric capacitor is formed on a portion of the first ILD layer 54 which is placed over the isolation region 51. The ferroelectric capacitor includes a bottom electrode 55, a ferroelectric layer 56 and a top electrode 57. A second ILD layer 58 covers the ferroelectric capacitor. After that, a first contact hole is formed on the top electrode 57 of the capacitor by removing a portion of the second ILD layer 58, thereby exposing a portion of top electrode 57. A second contact hole is formed on the source/drain regions 53A, 53B, 53C by opening a portion of the second ILD layer 58 and the first ILD 54 layer. An interconnection metal layer 59A connects the ferroelectric capacitor and the transistor through the first contact hole and the second contact hole. A HfO₂ layer 60 is formed on the whole structure including the first interconnection metal layer 59A. Finally, a second interconnection metal layer 61 covers the HfO₂ layer 60. The bit line 59B is electrically connected to the source/drain region 53B to apply an electric potential. Although the bit line 59B actually extends in right and left directions by passing the HfO₂layer 60, the drawing does not show these parts of the bit line 59B.

In the first and the second embodiments, the HfO₂ layers 38 and 60 function as an ILD layer which covers the whole structure including the ferroelectric capacitor, and as an intermetal dielectric, respectively. In the third preferred embodiment, the HfO₂ layer can cover only the ferroelectric capacitor.

FIG. 4 is a cross-sectional view showing a FeRAM device in accordance with the third preferred embodiment of the present invention. An isolation region 71 is formed on a semiconductor substrate 70, wherein the semiconductor substrate 70 is provided with a transistor including a gate dielectric layer (not shown) formed on the semiconductor substrate 70, a gate electrode 72, and source/drain regions 73A, 73B, 73C. A first ILD layer 74 covers the semiconductor substrate 70 including the transistor and the isolation region 71. A ferroelectric capacitor is formed on a portion of the first ILD layer 74 which is placed over the isolation region 71. The ferroelectric capacitor includes a bottom electrode 75, a ferroelectric layer 76 and a top electrode 77. A HfO₂ layer 78 covers the ferroelectric capacitor. A second ILD layer 79 covers the whole structure including the ferroelectric capacitor. After that, a first contact hole is formed on the top electrode of the capacitor by removing portions of the second ILD layer 79 and the HfO₂ layer 78, thereby exposing a portion of the top electrode 77. A second contact hole is formed on the source/drain regions 73A, 73B, 73C by opening portions of the second ILD layer 79 and the first ILD layer 74. An interconnection metal layer 80A connects the ferroelectric capacitor and the transistor through the first contact hole and the second contact hole. An intermetal dielectric layer 81 covers the whole structure including the interconnection metal layer 80A and the second ILD layer 79. The bit line 80B is electrically connected to the source/drain region 73B to apply an electric potential. Although the bit line 80B actually extends in right and left directions by passing the intermetal dielectric layer 81, the drawing does not show these parts of the bit line 80B.

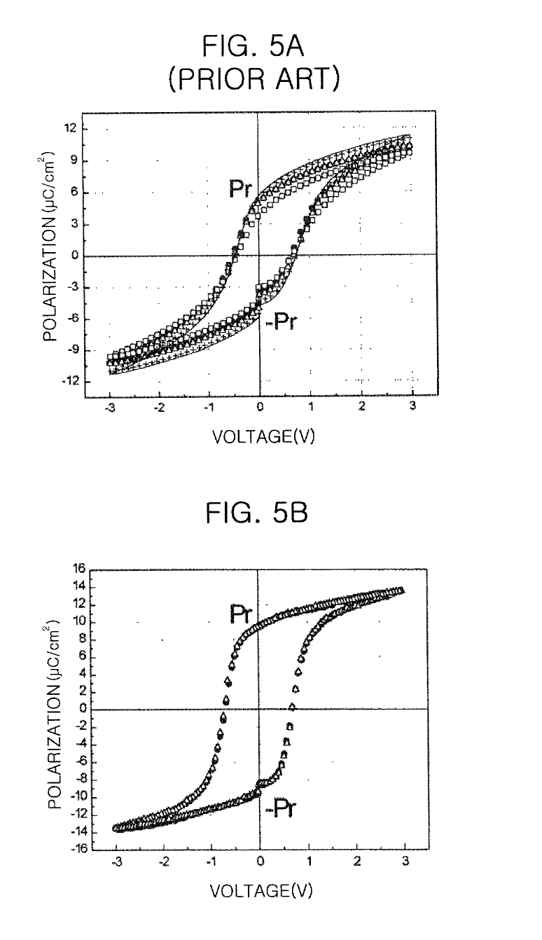

FIGS. 5A and 5B are graphs showing ferroelectric characteristics of polarization versus applied voltages for a conventional FeRAM device and for the present FeRAM device, respectively.

In the present invention, the HfO₂ layer is formed on the upper portion of the ferroelectric capacitor to increase device reliability.

While the present invention has been described with respect to the particular embodiments, it will be apparent to those skilled in the art that various changes and modifications may be made without departing from the scope of the invention as defined in the following claims.

What is claimed is:

1. A memory device, comprising:
a semiconductor substrate;
a ferroelectric capacitor provided with a bottom electrode placed on the semiconductor substrate, a ferroelectric layer formed on the bottom electrode and a top electrode formed on the ferroelectric layer; and
a HfO₂ layer for covering the ferroelectric capacitor.

2. A memory device, comprising:
a semiconductor substrate provided with a transistor formed thereon;
an interlayer dielectric (ILD) layer formed on the transistor and the semiconductor substrate;
a ferroelectric capacitor provided with a bottom electrode placed on the semiconductor substrate, a ferroelectric layer formed on the bottom electrode and a top electrode formed on the ferroelectric layer;
an interconnection metal layer for electrically connecting the ferroelectric capcitor to the transistor through the ILD layer; and
a HfO₂ layer formed on the interconnection metal layer.

3. The memory device of claim 2, further comprising:
an additional ILD layer formed on the ferroelectric capacitor except a portion where the interconnection metal layer makes contact therewith.

4. A memory device, comprising:
a semiconductor substrate provided with a transistor;
a first ILD layer formed on the transistor;
a ferroelectric capacitor provided with a bottom electrode formed on the first ILD layer, a ferroelectric layer formed on the bottom electrode and a top electrode formed on the ferroelectric layer;
a HfO₂ layer formed on the ferroelectric capacitor;
a second ILD layer formed on the HfO₂ layer and the first ILD layer;
a first contact hole to expose a portion of the transistor;
a second contact hole to expose a portion of the ferroelectric capacitor; and
an interconnection metal layer, formed on the second ILD layer, for electrically connecting the capacitor to the transistor.
